(19) United States
(12) Patent Application Publication
(10) Pub. No.: US 2003/0131939 A1
(43) Pub. Date: Jul. 17, 2003

(54) Apparatus and method for etching the edges of semiconductor wafers

(75) Inventors: Mark D. Rosenblum, Woburn, MA (US); Maurice P. Brodeur, Concord, MA (US); Bernhard P. Piwczyk, Dunbarton, NH (US); Brian H. MacKintosh, Concord, MA (US)

Correspondence Address: Pandiscio & Pandiscio, 470 Totten Pond Road, Waltham, MA, 02451, US

(73) Assignee: ASE Americas, Inc.

(21) Appl. No.: 10/051,899

(22) Filed: Jan. 17, 2002

(51) Int. Cl. H01L 21/461; C23F 1/00

(52) U.S. Cl. 156/345.51; 438/710

(57) ABSTRACT

Apparatus for use in edge etching a plurality of flat semiconductor wafers comprises a carousel releasably holding a plurality of carriers that are adapted to support a horizontal stack of wafers at selected points along the edges of the wafers. The carousel is adapted to be releasably attached to a dual axis rotary drive mechanism in a reaction chamber containing a plasma jet stream generator. The drive mechanism is operated to cause axis rotation of the carriers over the plasma jet stream, with selected edges of the wafers being directly exposed to and etched by the plasma. The etching process is interrupted to permit the carriers to be removed from the carousel for reorientation of the wafers. Thereafter, the etching process is resumed, whereby other edges of the wafers are subjected to etching by the plasma jet stream.

This invention was made under U.S. Government Subcontract No. ZAX-8-17647-10.

### FIELD OF THE INVENTION

This application relates to an apparatus and method for plasma etching the edges of semiconductor wafers, and more improvements on the apparatus and method disclosed in that improves International Patent Publication WO 00/52745.

### BACKGROUND OF THE INVENTION

International Patent Publication WO 00/52745, published Sep. 8, 2000 for an invention entitled “Etching Of Semiconductor Wafer Edges” and based on U.S. application Ser. No. 09/261,616, filed Mar. 3, 1999, by M. Kardauskas and B. Piwczyk, discloses an improved method and apparatus for etching the edges of semiconductor wafers for use in making solar cells, with the edge etching having as its chief purpose the elimination of microcracks. It is to be understood that the information disclosed in that patent publication is incorporated herein by reference.

The method and apparatus disclosed in International Patent Publication WO 00/52745 involves use of a plasma jet apparatus as disclosed in U.S. Pat. No. 5,767,627, issued Jun. 16, 1998 to O. Siniaguine. The Siniaguine plasma-generating apparatus generates a plasma jet that is magnetically shaped. That form of apparatus has been used for plasma processing of materials. U.S. Pat. No. 6,139,678, issued Oct. 31, 2000, and U.S. Pat. No. 6,238,587, issued May 29, 2001, provide further information regarding use of the plasma jet apparatus of Siniaguine. U.S. Pat. No. 6,139,678 illustrates a dual drive mechanism for rotating an article to be plasma processed relative to a plasma jet, with the mechanism being arranged to rotate the article around a first axis and simultaneously rotate the first axis around a second axis. The invention disclosed in U.S. Pat. No. 6,139,678 is incorporated herein by reference.

International Patent Publication WO 00/527415 discloses a carousel/wafer holder arrangement wherein a plurality of wafer coin stacks are supported by individual T-shaped holders or carriers, and those holders are hung on the periphery of the carousel so that the wafers extend vertically. The carousel is rotated so as to cause each of the coin stacks to pass in turn and repetitively over a plasma jet generator as disclosed by Siniaguine, with the carousel being disposed so that the bottom edges of the wafers briefly contact a selected region of the plasma jet. In processing square wafers, the etching operation is interrupted several times to permit the coin stacks to be rotated in their holders so that different edges of the wafers face down and are etched when the etching operation is resumed.

Unfortunately, the specific carousel/holder arrangement disclosed in International Patent Publication WO 00/52745 is not well suited for production requirements. Also the wafer carriers (holders) disclosed in that patent publication are not well suited for a production apparatus that utilizes a dual axis rotational drive system for the carousel.

### OBJECTS AND SUMMARY OF THE INVENTION

The primary object of the invention is to provide improved carousel and wafer holder apparatus for use in edge etching semiconductor wafers using a plasma jet generator as disclosed by Siniaguine and a carousel drive mechanism as disclosed by Siniaguine in U.S. Pat. No. 6,139,678.

Another object of the invention is to provide an improved carousel/wafer carrier assembly whereby the wafers may be efficiently edge-etched by a plasma jet generator.

Another object of the invention is to provide improved forms of carriers for coin stacks of wafers, with the carriers being arranged for disposition in openings in a carousel.

Another object is to provide improved wafer carriers that are designed to hold a stack of square wafers so that two side edges of each wafer are exposed simultaneously for contact with a reactive plasma stream.

These and other objects hereinafter rendered apparent are achieved by providing carriers that are adapted to support wafer coin stacks at selected points along their edges. The carriers are mounted to a carousel that is adapted to be releasably secured to a dual axis rotary drive mechanism, and which has openings for receiving the carriers, plus means for holding the carriers in a selected depending relationship with the carousel. The carriers are designed to facilitate insertion and removal of wafers. The carousel/multiple carrier assembly is attached to the drive mechanism in a reaction chamber and the drive mechanism is operated to cause rotation of the carousel over a plasma jet stream, with selected edges of the wafers being directly exposed to the plasma. The etching process is interrupted to permit the carousel to be withdrawn from the reaction chamber so that the carriers can be removed from the carousel for reorientation of the wafers. Thereafter, the carriers are remounted to the carousel and the carousel/multiple carrier assembly is returned to the reaction chamber and attached to the drive mechanism, whereby other edges of the wafers are subjected to etching by the plasma jet stream.

Other features and advantages of the invention are rendered apparent by the following detailed description of preferred and alternative embodiments of the invention.

### THE DRAWINGS

FIGS. 1 and 2 are schematic views in side elevation of plasma processing equipment embodying a plasma jet generator, a carousel supporting a plurality of carriers for edge etching in the reaction chamber, and a dual axis rotational drive mechanism for supporting and rotating the carousel;

FIG. 3 is a perspective view of a preferred form of wafer carrier embodying the invention;

FIG. 4 is a fragmentary sectional view in elevation of one side of the carrier of FIG. 3;

FIG. 5 is an exploded view of the same carrier;

FIG. 6 is a partially exploded view of a half section of one of the two component subassemblies of the carrier of FIG. 3;

FIG. 7 is a plan view of a carousel for supporting the carriers shown in FIGS. 1-6;

FIG. 8 is a bottom view of the same carousel;

FIG. 9 is a fragmentary sectional view in elevation taken through the center of the carousel of FIGS. 7 and 8;

FIG. 10 is a downward perspective view illustrating the same carousel loaded with a plurality of carriers;

FIG. 11 is a schematic view illustrating wafer orientation in the carriers of FIGS. 3-6;

FIG. 12 is a perspective view of a second form of carrier provided according to the present invention;

FIG. 13 is a fragmentary sectional view of one side of the carrier of FIG. 12;

FIG. 14 is an exploded view of the two component portions of the carrier of FIG. 12;

FIG. 15 is a partially exploded view of one of the two half sections of the same carrier;

FIG. 16 is a top perspective view of a modified form of carousel together with one of the carriers shown in FIGS. 12-15;

FIG. 17 is a fragmentary perspective view of a portion of the carousel of FIG. 16;

FIG. 18 is a perspective view of a third form of carrier provided by the invention; and

FIG. 19 is a fragmentary cross-sectional view of a portion of the carrier of FIG. 18.

### DETAILED DESCRIPTION OF THE INVENTION

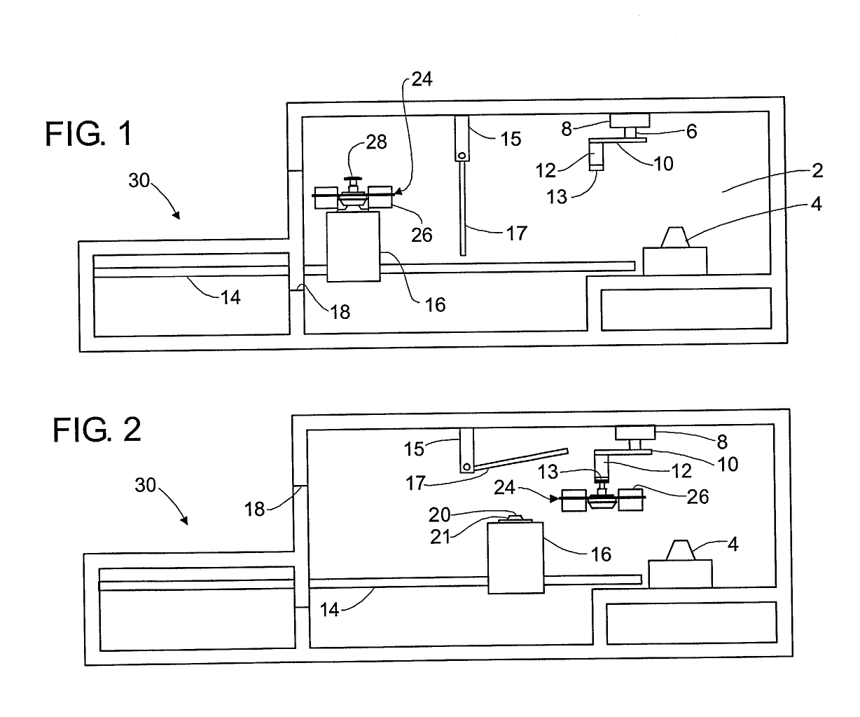

Referring now to FIGS. 1 and 2, there is shown apparatus comprising an enclosure 2 having a plasma jet reaction chamber 2 within which is mounted a plasma jet generator represented schematically at 4, and a carousel rotating mechanism comprising a first vertically-extending rotatable shaft 6 carried by a rotary drive 8, an arm 10 on the end of the shaft 6, and a rotary drive 12 carried by arm 10 that rotatably carries a carousel holding means 13. The plasma jet generator, which preferably is like that disclosed by Siniaguine in U.S. Pat. No. 5,767,627, is operated so as to provide a reactive plasma of selected composition, e.g., a plasma comprising halogen ions for edge etching silicon wafers produced by the EFG process, as disclosed in International Patent Publication WO 00/52745, supra.

Drive 8 is fixed to the chamber. The carousel holding means 13 rotates on a vertical axis when drive 12 is energized and is adapted to releasably hold a carousel as described hereinafter. Carousel holding means 13 is remotely actuated and controlled (by conventional means not shown) and may take various forms. Thus it may be a pneumatic, electromechanical or electromagnetic device. The apparatus also includes a vertical partition 15 that pivotably supports a remotely-operated door 17. The latter pivots on a horizontal axis between a down closed position and a raised open position. The apparatus also includes a horizontal track 14 that movably supports a shuttle mechanism 16. The shuttle is adapted to move outside of the reaction chamber via an opening 18 of suitable size that is closed off by a sliding door (not shown). The shuttle carries a carousel support member 20 that is movable vertically a selected distance by a remotely controlled elevator mechanism (not shown) which forms part of the shuttle 16. In FIGS. 1 and 2, carousel support member 20 is shown in its down position. The carousel holder 13 is adapted to support a carousel 24 (provided according to the present invention) that carries a plurality of wafer carriers 26 (also provided according to the present invention). Support member 20 preferably has a frustoconically shaped outer surface 21 for supporting the carousel, as further described hereinafter.

The carousel has an upstanding center hub 28. A computer-controlled drive means (not shown) operates to move shuttle 16 on track 14 from a first carousel pickup/release position outside of the reaction chamber, represented generally by the area identified by the numeral 30, through opening 18 into the reaction chamber to a second intermediate position short of partition 15 and its door 17. Door 17 is in its down position during this step, so as to block human viewing access to the UV light that is produced by the plasma generator. After the opening 18 has been closed by its door (not shown), door 17 is raised, and the shuttle is moved to a third position where hub 28 of the carousel is aligned with and engages carousel holding means 13. Movement of the carousel into alignment with the carousel hub 28 occurs with carousel support 20 in its raised position, with the carousel support being moved from its down position to its elevated position while the shuttle is in its first position outside of the reaction chamber. Once the carousel hub is locked to holding means 13, carousel support member 20 is lowered to its down position and then the shuttle is retracted from beneath the carousel which is now supported solely by holding means 13 (FIG. 2). The shuttle is returned to its second intermediate position. Thereafter, the drives 8 and 12 are operated to cause the carousel to rotate above the plasma jet stream generator 4, with the carousel rotating first about the vertical axis of drive 8 and secondarily about the vertical axis of drive 12, in the manner described in Siniaguine U.S. Pat. No. 6,139,678.

Removal of the carousel from the reaction chamber is straightforward and involves the following steps: (1) drives 8 and 12 are stopped, (2) the shuttle is moved to bring carousel support 20 into center alignment with the carousel, (3) carousel support 20 is engaged with the carousel and the carousel is released from holding means 13, (4) with door 17 again in raised position, the shuttle carrying the carousel is moved back to its second intermediate position, (5) door 17 is re-closed, (6) the door to opening 18 is moved to open position, and (7) the shuttle moves the carousel through opening 18 back to the carousel pickup/release area 30. Although not shown, it is to be understood that in the pickup/release area 30 a carousel handling mechanism (not shown) is provided for holding a carousel in position to be engaged by carousel support 20 and for lifting a carousel off of carousel support 20 for removal of wafers or rotation of the carriers as hereinafter described.

With the exception of carousel 24 and carriers 26, the apparatus illustrated in FIGS. 1 and 2 and hereinabove described, is conventional and forms no part of the present invention. In this connection, it should be noted that an apparatus the same as that schematically illustrated in FIGS. 1 and 2, but excluding carousel 24 and carriers 26, is commercially available from Tru-Si Corporation of Sunnyvale, Calif.

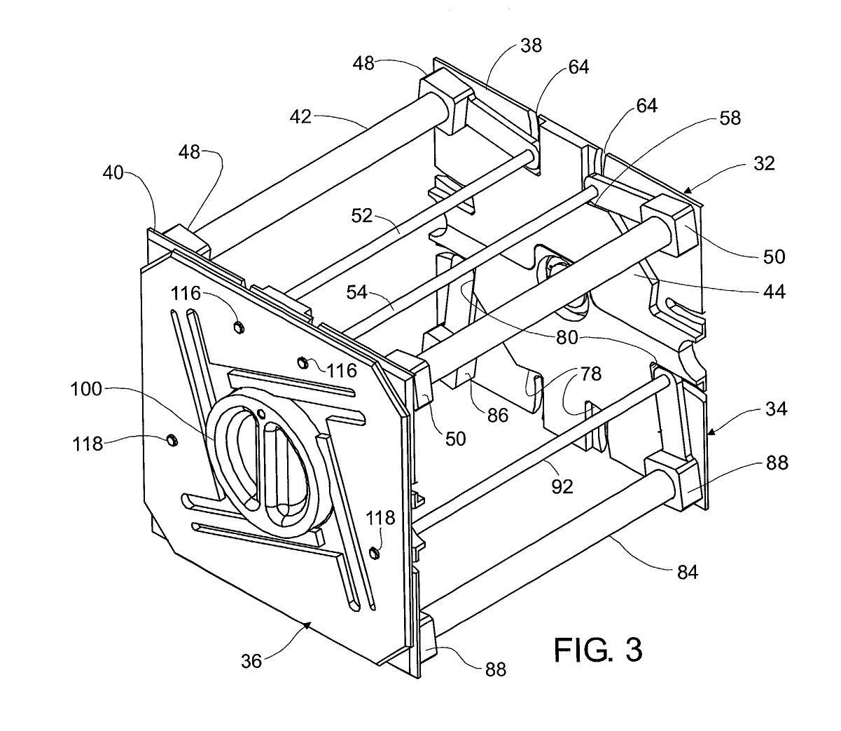

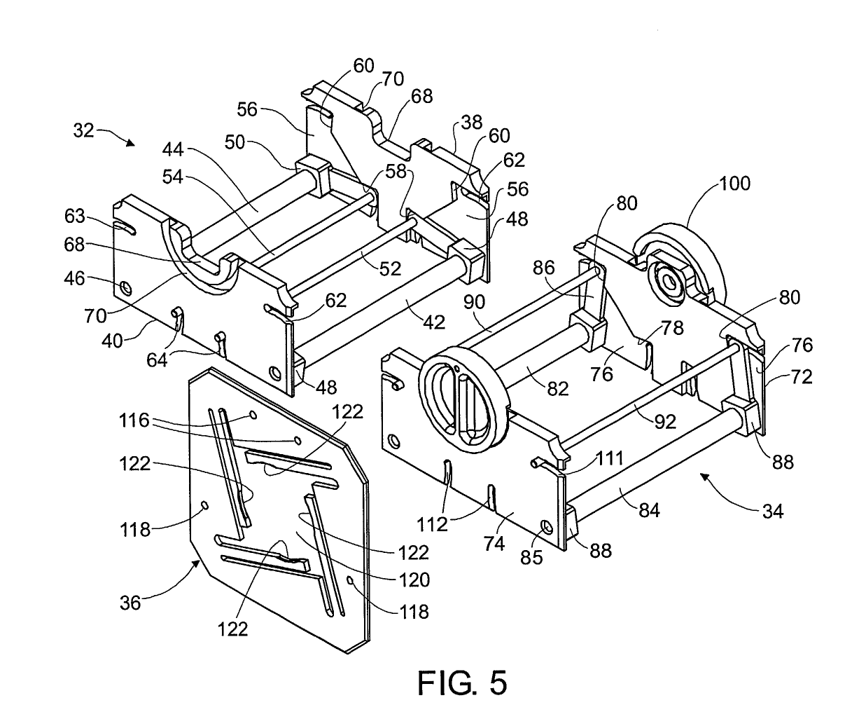

The present invention provides several forms of wafer carriers 26, as well as carousels adapted to support a number of those carriers, with each carrier capable of holding a horizontal stack of vertically aligned wafers to be etched. Referring now to FIGS. 3-6, a first preferred form of wafer carrier is shown that comprises three distinct parts, designated generally in FIG. 5 by the numerals 32, 34 and 36. The parts 32 and 34 essentially form complementary halves of the carrier. The part 32 comprises a pair of square like side plates 38 and 40 that extend parallel and are spaced from one another and are connected by a pair of pivot shafts 42 and 44. The shafts are connected to side plates 38 and 40 by screws 46 (FIG. 5) that fit in countersunk holes in the plates 38 and 40 and screw into the ends of shafts 42 and 44. Rotatably mounted on shaft 42 are two arms 48. Two like arms 50 are rotatably mounted on shaft 44. The free ends of arms 48 are connected by a wafer support rod 52. A second like wafer support rod 54 is attached and extends between the free ends of arms 50. Side plates 38 and 40 are relieved on their inner sides so as to form recessed surfaces 56 and two pairs of shoulders 58 and 60 that act as stops for arms 48 and 50 adjacent their connection to wafer support rods 52 and 54. Plates 38 and 40 also have like slots 62, 63 and 64 cut in adjacent edges, and wafer support rods 52 and 54 project through arms 48 and 50 far enough to extend into the slots 62 and 63, or slots 64, depending upon the position of those arms as hereinafter described. Additionally, side plates 38 and 40 have edge notches 68 that are located substantially centrally of the two plates, and two semicircular grooves 70 formed in their outer surfaces in concentric relation to notches 68.

The second part 34 of the carrier comprises two like side plates 72 and 74 that are like the plates 38 and 40 in that their inner surfaces are undercut as shown at 76 to form shoulders 78 and 80 corresponding to shoulders 58 and 60. Plates 72 and 74 are secured to two pivot shafts 82 and 84 by screws 85 that fit in countersunk holes in those plates and screw into the ends of the shafts. A pair of arms 86 and 88 are rotatably mounted on the opposite ends of shafts 82 and 84 respectively, and the free ends of arms 86 and 88 are coupled together by wafer support rods 90 and 92.

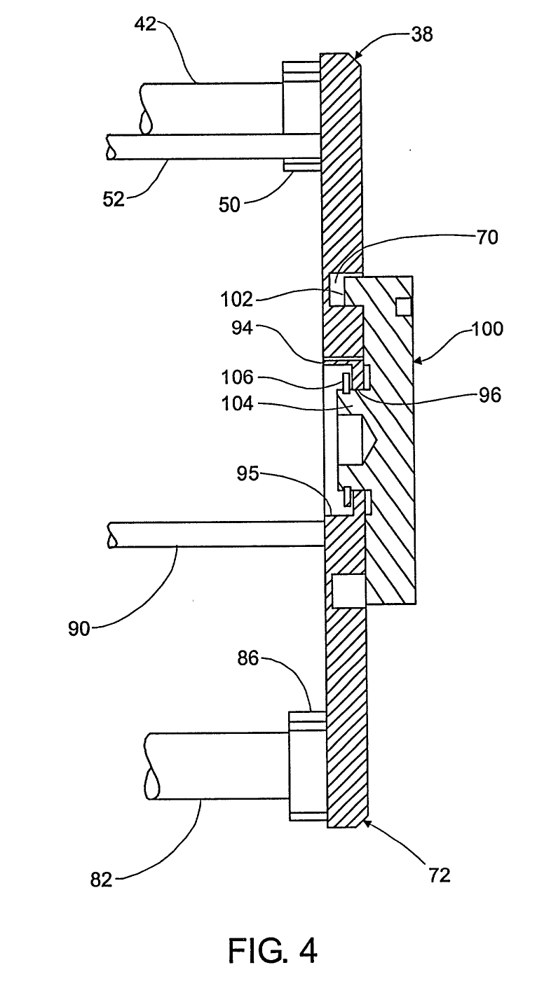

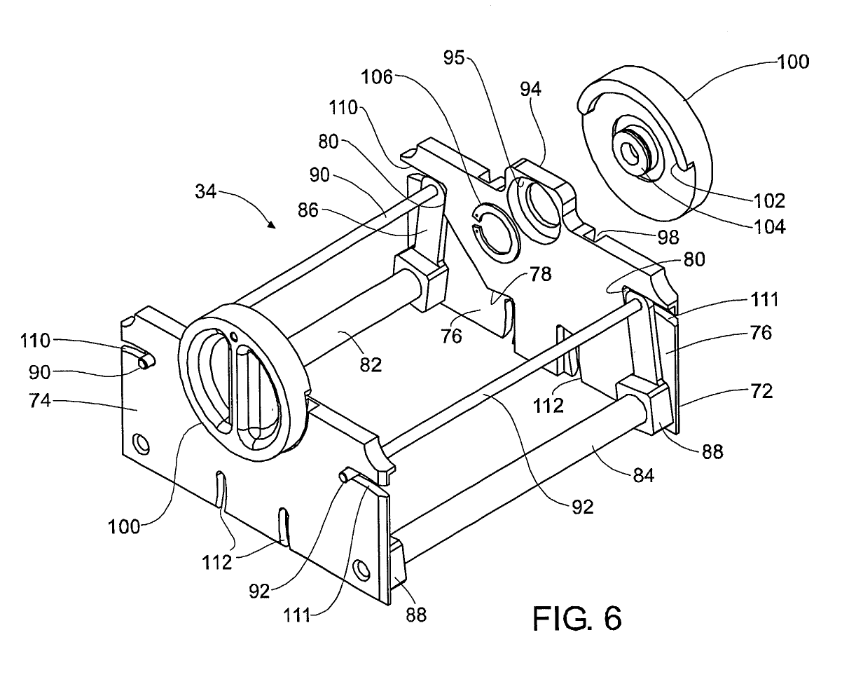

Still referring to FIGS. 4 and 5, side plates 72 and 74 are provided with upstanding lug portions 94 on their upper edges. Lug portions 94 are shaped and sized to fit in edge notches 68. The inner surface of each side plate 72 and 74, including lug portion 94, has a circular depression 95 that surrounds a through hole 96 (FIG. 4). Plates 72 and 74 have semicircular grooves 98 in their outer surfaces that complement grooves 70, i.e., they have the same radius and cross-sectional size. Attached to the lug portions 94 are two wheels 100. Referring to FIGS. 4 and 6, each wheel 100 has a semicircular rib 102 projecting from its inner surface. Ribs 102 are sized to make a sliding fit in grooves 70 and 98. Wheels 100 have axial hubs 104 that are sized to make a close rotational fit in holes 96 in plates 72, 74. The hubs 104 are provided with peripheral grooves that are sized to receive a snap lock ring 106. The latter engage the inner surfaces of plates 72 and 74 around holes 96, whereby to retain the wheels 100 in place. Wheels 100 are sized so that when the two sections 32 and 34 are brought together in the manner shown in FIG. 3, rotation of those wheels will move the ribs 102 into the grooves 70, thereby locking the parts 32 and 34 together.

As with the part 32, the wafer support rods 90 and 92 protrude through the arms 86 and 88, and side plates 72 and 74 are provided with slots on three sides, as shown at 110, 111, and 112 corresponding to slots 62, 63 and 64 respectively. These slots are in position to receive the ends of the wafer support rods 90 and 92 according to the rotational position of arms 86 and 88.

The third part 36 of the carrier illustrated in FIGS. 3-6 is a lock plate that is provided with two pairs of holes 116 and 118 that are sized to receive the ends of wafer support rods 52, 54, 90 and 92. Lock plate 36 also has a large convoluted opening 120 that includes circularly curved edge surfaces 122 that are spaced to accommodate wheels 100. Holes 116 are spaced apart a distance equal to the spacing between the ends of support rods 52 and 54 (and also between rods 92 and 94) when they are disposed in slots 64 (or slots 112 in the case of rods 90 and 92). Holes 118 are spaced apart a distance equal to the spacing between the ends of support rods 52 and 54 when they reside in slots 62 and 63 (the spacing is identical when rods 90 and 92 reside in slots 110 and 111). Plate 36 can be repositioned, as described hereinafter. In the position shown in FIGS. 3 and 5, holes 116 are positioned to receive the ends of rods 52 and 54 and lock them in slots 64, while holes 118 receive the ends of the rods 90 and 92 and lock them in slots 110 and 111. If lock plate 36 is repositioned by rotating it 180° from the position shown in FIGS. 3 and 5, holes 118 will be disposed to receive the ends of rods 52 and 54 and lock them in edge slots 62 and 63 and holes 116 will be disposed to receive the ends of lock rods 90 and 92 and lock them in edge slots 112.

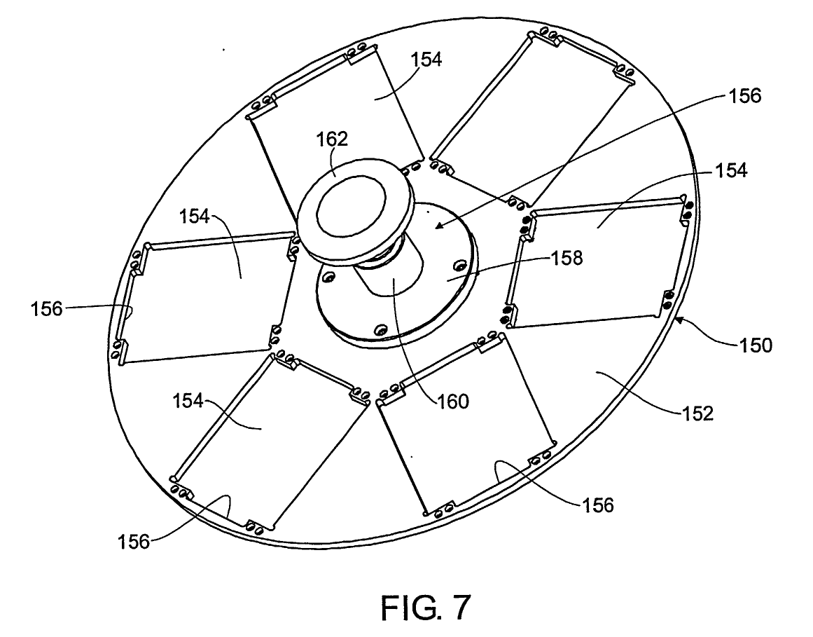

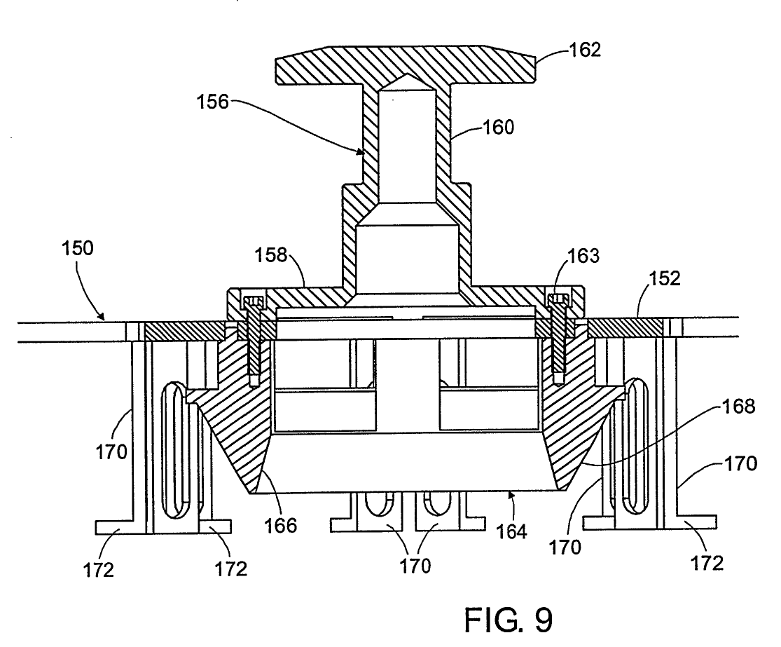

Turning now to FIGS. 7-9, there is shown a carousel 150 comprising a metal plate 152 having a series of uniformly spaced generally rectangular openings 154 arranged in a circular array around its center. Openings 154 are sized to receive the carriers shown in FIGS. 3-6 with the side plates of the carriers extending at a right angle to radial planes through the center of the carousel. The wheels 100 protrude from the outer side surfaces of the assembled carrier, and also beyond the outer surface of each plate 36. Accordingly, the inner and outer sides of openings 154 are notched as shown at 156 to accommodate wheels 100. Attached to the upper side of carousel plate 152 is a support hub 156 comprising a flange 158. The hub also comprises an axial portion 160 and an enlarged head 162 that enables the hub to be gripped by the holding means 13. Referring now to FIG. 9, hub 156 is coupled by fasteners 163 to plate 152 and a hollow member 164 on the underside of plate 152. Member 164 has inclined inner and outer surfaces 166 and 168 on its bottom side. The slope and inside diameter of inside surface 166 are arranged to allow that surface of member 164 to seat closely on the similarly tapered outer surface 21 of carousel support member 20, whereby the carousel may be supported by support member 20 without need of any auxiliary restraining means.

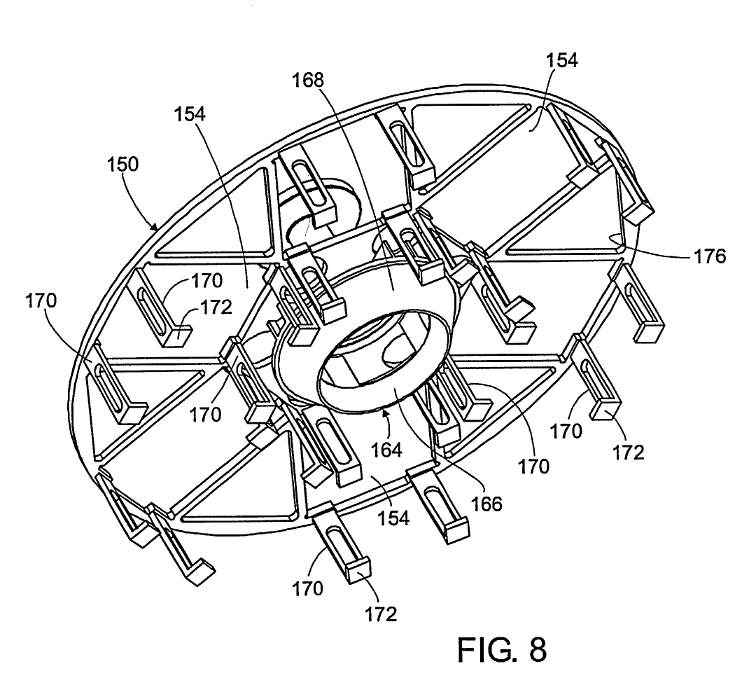

Still referring to FIGS. 8 and 9, the underside of the carousel 156 is provided with a plurality of depending legs 170, two each at the inner and outer sides of each opening 154. Legs 170 are L-shaped, having interned flanges or feet 172 at their bottom ends. Preferably, but not necessarily, the underside of the plate 152 is provided with recesses 176 (FIG. 8) between holes 154 for the purpose of reducing the overall weight of the carousel.

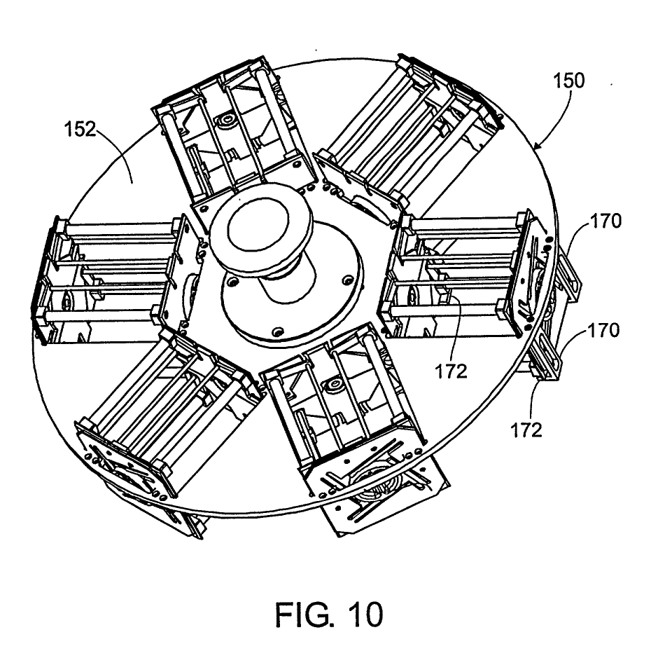

FIG. 10 shows the carousel 150, plus a carrier made up of parts 32 and 33 and a lock plate 36 in place in each of the openings 154. The carriers are illustrated in their empty state, i.e., without any wafers to be etched. For convenience of illustration, FIG. 10 omits the legs 170 from all but one of the openings 154. However, it is to be considered that in practice each opening 54 has depending legs 170 for supporting a carrier assembly. The bottom edges of plates 72 and 74 (or the corresponding edges of plates 38 and 40 depending on the orientation of the carriers in the openings 154), and also the bottom edges of lock plates 36, are engaged with and supported by the feet 172 of legs 170.

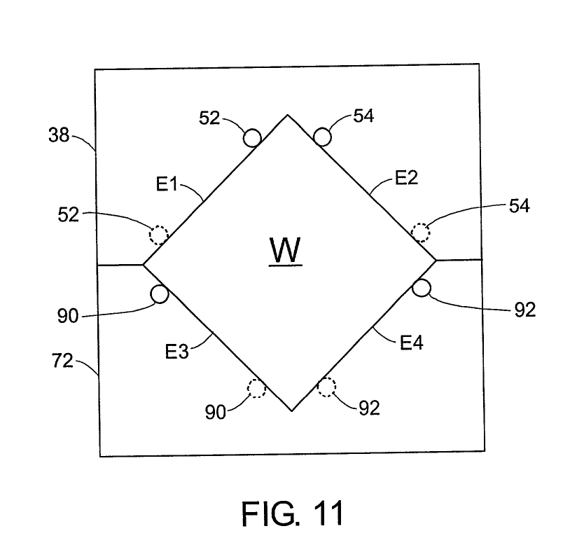

Wafers are loaded into the carriers of FIGS. 4-6 by rotating wheels 100 so as to free ribs 102 from grooves 70 in plates 38 and 40, whereby the part 32 may be separated from part 34. Then, with arms 86 and 88 positioned against the shoulders 80 as shown in FIGS. 3 and 5, a stack of rectangular wafers W are positioned on support rods 88 and 90 of the carrier part 34 in the manner illustrated schematically in FIG. 11. Thereafter, carrier part 32, with arms 48 and 50 engaged with shoulders 58, is placed on top of carrier part 34, and locked thereto by rotating wheels 100 so that their ribs 102 move into grooves 70. Lock plate 36 is then positioned against plates 40 and 74 (or against plates 38 and 72) to lock the support rods against movement. The carrier is then inserted in an opening 154 of the carousel where it engages and is supported by feet 172.

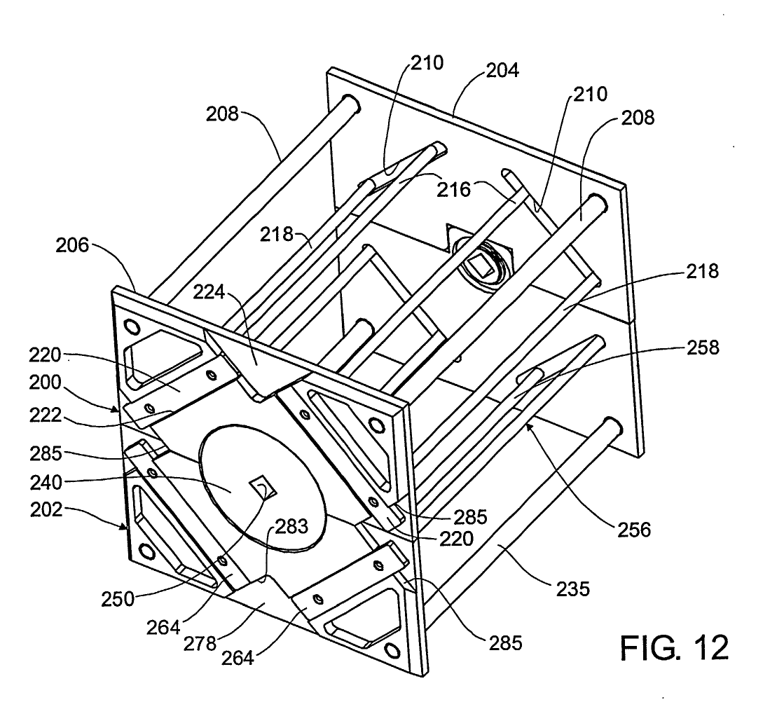

FIG. 11 illustrates the orientation of the wafers in a carrier as described above. In FIG. 11, the side plates 38 and 72 are represented schematically as two rectangles with the plates oriented as in FIG. 3. The instant positions of wafer support rods 52, 54, 90 and 92 are represented by the solid line circles, while the other alternate portions of those rods are represented by the broken line circles. In FIG. 12, a wafer stack is represented in end view by a rectangular wafer W. The latter is shown resting on support rods 90 and 92 that are in the position illustrated in FIG. 5. The other two support rods 52 and 54 are in the same position as shown in FIG. 3. In such position, the rods 52 and 54 are closer to one another than are the support rods 90 and 92. Hence, rods 52 and 54 engage the wafer adjacent the corner formed by the wafer edges E1 and E2, while the rods 90 and 92 engage the wafer near the centers of the wafer edges E3 and E4. When the carrier is mounted on the carousel with the orientation shown in FIG. 6, the bottom edges of side plates 72 and 74 will rest on feet 172. Assuming that like carriers, each carrying a like stack of wafers, are similarly disposed in all of the openings 154 of the carousel, when the carousel is moved into reaction chamber 2 and attached to holding means 13, the two edges E3 and E4 (of the wafers in each stack) engaged with supports rods 90 and 92 will be closest to the level of the plasma jet produced by generator 4 and, therefore, will undergo etching at a relatively fast rate. In contrast, the other two edges E1 and E2 of the wafers in each stack are located further away from the plasma jet and, therefore, undergo a lesser degree of etching as the carrier is moved repetitively past the plasma jet.

As described in International Patent Publication No. WO 00/52745, supra, the etching process needs to be interrupted to permit the wafers to be reoriented in order to etch all of the edges of the wafers uniformly. Preferably this is accomplished without shutting down the plasma generator. Accordingly, after the edges E3 and E4, for example, have been exposed to the plasma jet for a sufficient period of time to etch away portions of those edges of all of the wafers in the several stacks contained in the several carriers, the drive means 8 and 12 are deactivated to stop rotation of the carousel, and then support member 20 is elevated into contact with the carousel and the holding means 13 is caused to release the carousel so that it rests on support member 20. Then support member 20 is lowered and shuttle 16 is operated to carry the carousel out of the reaction chamber. Once the carousel is outside of the reaction chamber, the carriers and carousel are allowed to cool. Then the carriers are removed from the carousel and the lock plates 36 are separated from the carriers.

Then the assemblies comprising rods 52 and 54 and arms 48 and 50 are pivoted to move rods 52 and 54 into edge slots 62 and 63, and the other assemblies comprising rods 90 and 92 and arms 86 and 88 are pivoted to place rod 90 and 92 in edge slots 112. The lock plates 36 are then replaced, with rods 52 and 54 received in holes 118 and rods 90 and 92 in holes 116. In such position, support rods 52 and 54 are now spaced further apart from one another, while the support rods 90 and 92 are more closely spaced to one another. More specifically, now support rods 90 and 92 engage the wafers closer to the corners formed by the edges E3 and E4, and the support rods 52, 54 now engage the edges E1 and E2 a further distance from the corner formed by those edges. The purpose of rotating the support rods is to expose the areas of the edges E1-E4 that had been contacted and concealed by the four support rods during the previous etching steps, since the amount of etching experienced by those contacted areas of edges E1-E4 is noticeably less than the etching experienced by the remainder of those edges.

Thereafter the carriers are reversed 180° and in that reverse position, they are re-inserted into openings 154. With the new reversed orientation of the carriers, the edges E1 and E2 are now closest to the plasma jet and undergo preferential etching. Then in sequence the carousel with the reversed carriers is returned to the reaction chamber, support member 20 is elevated to place the carousel in contact with holding means 13, the holding means is activated to grasp the carousel hub, support member 20 is lowered, shuttle 16 is retracted, and dual axis rotation of the carousel is resumed to conduct further etching.

Once the edges E1 and E2 of the wafers in the carriers have been etched a selected amount, rotation of the carousel is again terminated, and the carousel is again released from holding means 13 and removed from the reaction chamber by the shuttle mechanism. After cooling the carriers are removed from the carousel and the carriers opened to permit unloading of the etch wafers. The carriers are opened by rotating wheels 100 to unlock carrier part 32 from carrier part 34, after which those parts are separated to permit access to the wafers.

With carriers of the preferred type shown in FIGS. 3-7, the reorientation of the wafers in the carriers needs to be conducted only once in order to achieve controlled etching to an acceptable depth of each of the edges E1-E4 of the wafers.

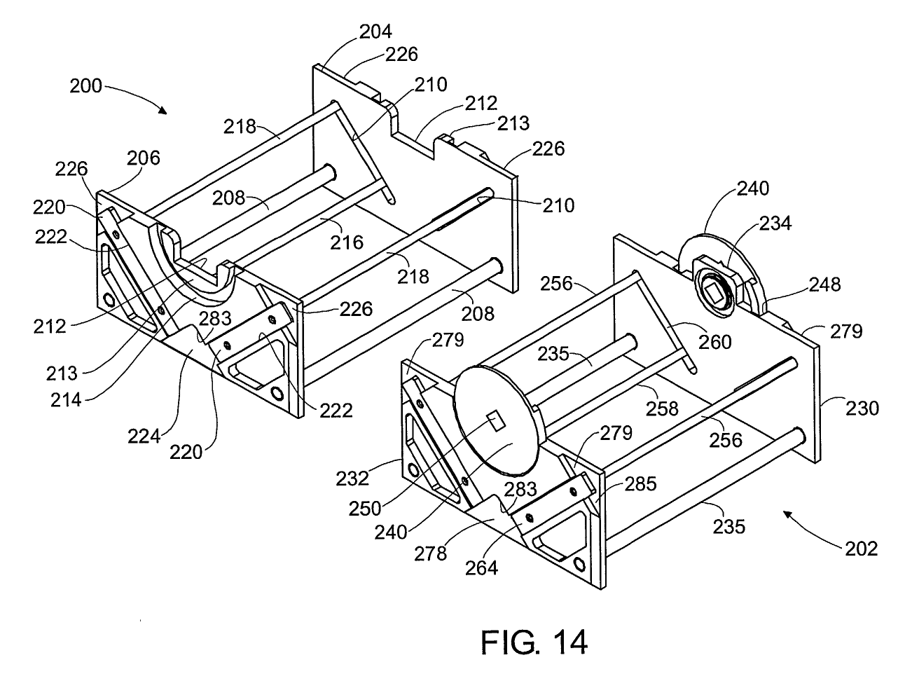

FIGS. 12-15 illustrate an alternative form of carrier embodying the present invention. In this case the carrier comprises two parts 200 and 202. The part 202 comprises a pair of side plates 204 and 206 that are tied together by two tie rods 208. The latter may be secured to the plates by fasteners, a force fit or other suitable connection means. Plates 204 and 206 are essentially identical, each of them has a pair of oppositely inclined elongate openings 210 (FIG. 14). These openings are disposed at approximately 45° angles to the edges of the two plates. Plates 204 and 206 each have a centrally located notch 212 along one edge. Additionally, the outer face of plate 154 and 156 is formed with a recessed surface 213 and a semicircular groove 214. Extending through each of the openings 210 in both plates are two pairs of wafer support rods 216, 218. The outer ends of each pair of wafer support rods are fixed to like slide bars 220. The latter are flat and slidably mounted in grooves 222 that are formed in the outer surfaces of plates 204 and 206 and are aligned with openings 210. Slide grooves 222 have a width larger than the corresponding dimension of openings 210.

The outer surfaces of plates 204 and 206 are also provided with a triangular, flat-bottomed recess 224 that is in intersecting relation with one end of the adjacent slanted grooves 222. The outer surfaces of plates 204, 206 also have two triangular recesses 226 at opposite corners that intersect grooves 222. The spacing between the rods 216 and 218 is less than the overall length of the slide bars 220 and less than the length of the elongated holes 210, with the result that each assembly comprising support rods 216 and 218 and two slide bars 220 can move along an inclined path as determined by grooves 222 and openings 210.

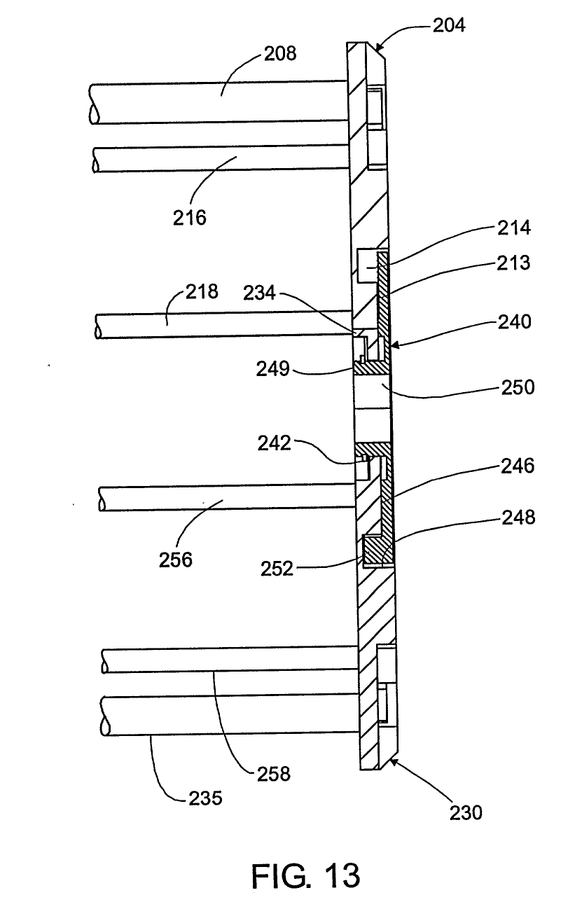

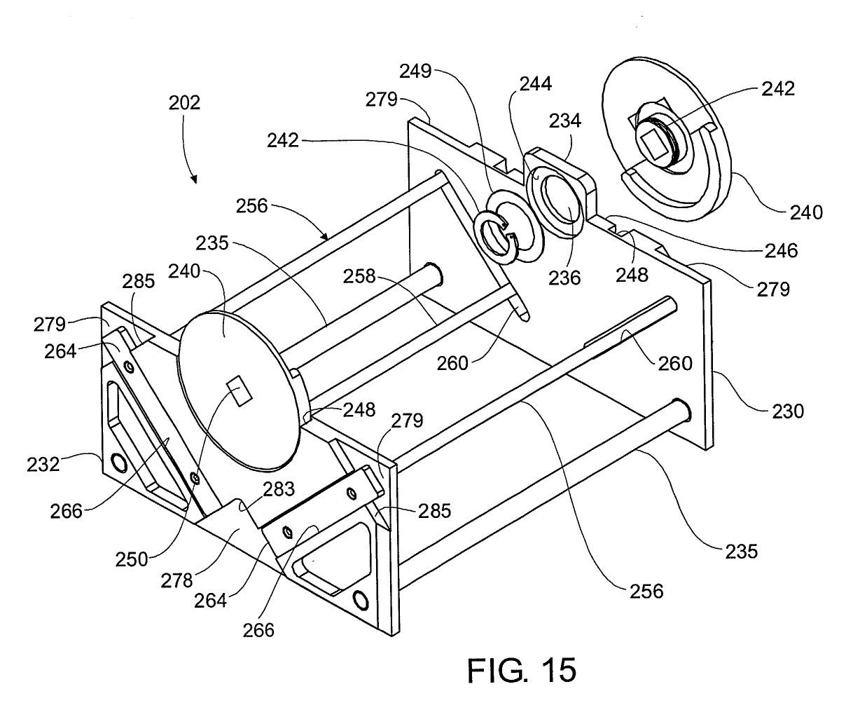

Referring to FIGS. 14 and 15, the second part 202 of the carrier comprises a pair of like side plates 230 and 232 that are formed with upstanding lug portions 234 along one edge. Plates 230 and 232 are tied together by tie rods 235. As seen best in FIGS. 13 and 15, each lug portion has a center hole 236 that is sized to receive the cylindrical hub 242 of a wheel 240. Two identical wheels 242 are provided, one for each side plate. A circular counterbore 244 surrounds hole 236 on the inner side of each plate 230 and 232. The outer sides of plates 230 and 232 have a depression 246 and a semicircular groove 248 around hole 236 to accommodate the wheel 240. A low friction bearing member 249 in counterbore 244 surrounds hub 240. The hub of each wheel 240 has a peripheral groove to accommodate a snap ring 242 that serves to rotatably lock the wheel to plates 230 and 232. Preferably, the wheels have a shaped center hole 250 that serves as a keyway to accommodate a key for rotating the wheels. Each of the wheels also has a semicircular rib 252 that is sized to slidably fit in semicircular groove 248 formed in the outer face of side plates 230 and 232 and also in groove 214 of the other part of the carrier.

A pair of wafer support rods 256 and 258 extend through inclined like elongated holes 260 in each of the plates, and the opposite ends of support rods 256 and 258 are attached to slide bars 264. The latter reside in oppositely inclined grooves 266 formed in the outer faces of plates 230 and 232. These grooves extend at an angle of 45° to side edges of the side plates. The outer faces of side plates 230 and 232 also have a triangular depression 278 that intersects one end of each of the grooves 266. Two other triangular depressions 279 at corners of the side plates intersect the opposite ends of groove 266. As with the other part of the carrier, the holes 260 are long enough to permit the rods 256 and 258 to move lengthwise of the holes.

Referring again to FIGS. 12-15, the carrier is assembled by positioning the two mating parts of the carrier face to face as shown in FIG. 12 so that the notches 212 receive the lug portions 234, and then the two parts are secured together by rotating wheels 240 until their ribs 252 reside in the grooves 214 of plates 204 and 206. It should be noted that the outer sides of wheels 240 are flush with the outer surfaces of side plates 204, 206, 230 and 232.

A stack of square wafers is disposed in the carrier by separating the two parts and, for example, resting the stack of wafers on rods 256 and 258 of the second carrier part 202. Thereafter, the other carrier part 200 is placed over the wafers and locked to the first section by rotation of the wheels 240. When this is done, the wafers are engaged on four sides, in an arrangement similar to that shown in shown in FIG. 11, with the four corners of the wafer being in the 3, 6, 9 and 10 o'clock positions. When the two sections of the carrier are assembled together with a stack of wafers in place, the wafer support rods can be shifted along the length of the holes 210 and 260. Such shifting movement is provided to overcome the “shadow” effect of the rods, i.e., the non-etching of portions of the wafer edges due to being engaged by the support rods.

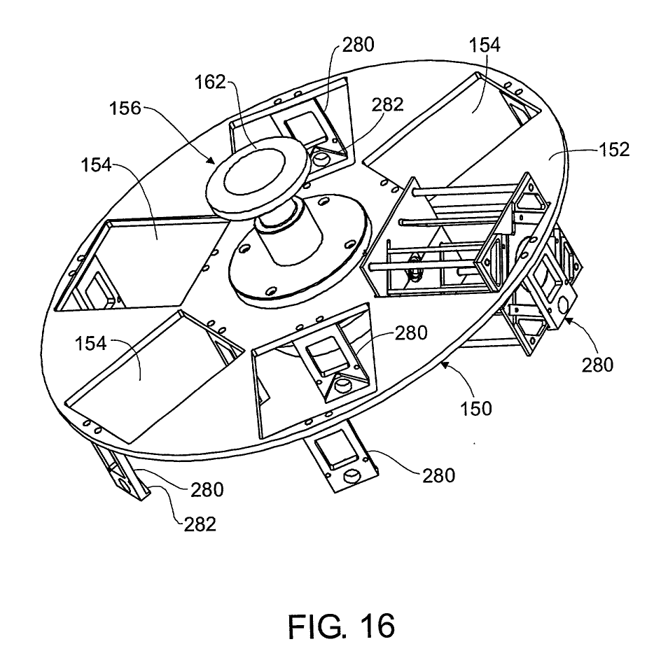

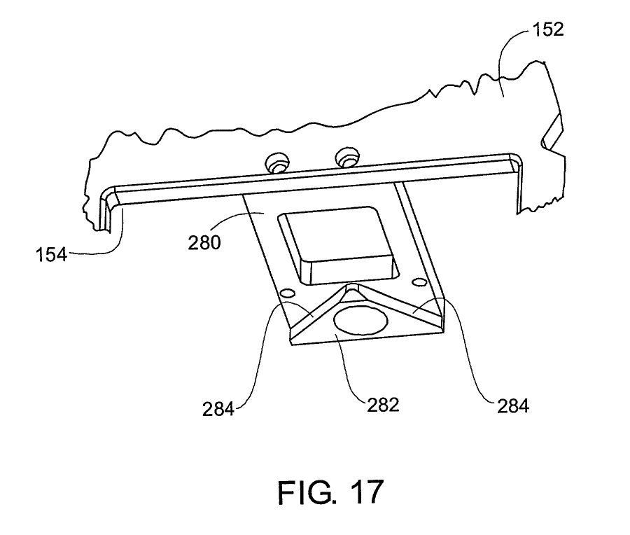

FIGS. 16 and 17 illustrate a modified form of carousel for use with the second form of carrier just described. The carousel is substantially the same as the carousel of FIGS. 7-9; therefore, like elements are identified by like numerals. This modified form of carousel differs in that openings 154 do not require notches 156 since wheels, and also a pair of depending legs 280 are associated with each of rectangular openings 154. Legs 280 are disposed at the inner and outer edges of the rectangular openings. The mutually confronting surfaces of each pair of legs 280 are formed with a protruding abutment 282 of triangular shape, each such abutment having oppositely inclined upper edge surfaces 284 that extend at 45° angles (more accurately angles of 45° and 135°) to plate 152.

The abutment 282 acts as a stop for the slide bars of the carrier. When an assembled carrier holding a stack of wafers is inserted in one of the carousel openings 154, the abutments 282 engage the edge surfaces 283 or 285 of the triangular recesses or depressions 224, 226, 278 and 279, and thereby support the carrier in opening 154. The slide bars 220 and/or 264 (depending on how the carrier is oriented in opening 154) will engage the upper inclined surfaces 284 of abutments 282, forcing the slide bars to move upwardly in their side plate grooves relative to the carrier assembly.

Assume that the carrier, filled with a stack of wafers that extends fully between the side plates of the carrier and oriented as shown in FIG. 12, is inserted into one of the openings 154 of the carousel. The wafers will occupy essentially the same angular position relative to the carrier side plates as is shown schematically in FIG. 11. When the carrier is inserted, slide bars 264 will be cammed upwardly by abutments 282, so that the support rods 256 and 258 will be in their uppermost position in elongate holes 260. Simultaneously, however, the other wafer support rods 216 and 218 will be in their lowermost position, the position shown in FIG. 12, as a consequence of gravity and the fact that the slide bars 220 can extend into the adjacent corner recesses 226. Hence, the support rods 216 and 218 will engage the adjacent edges of the wafers at different points than the points of engagement of the support rods 256 and 258 with the wafers.

Edge etching stacks of wafers held in the carriers of FIGS. 12-15 and using apparatus as illustrated in FIGS. 1 and 2 involves interruption of the etching process to change the rotational position of the wafers so that different pairs of edges directly face the plasma generator. After the wafers held in such carriers have been exposed repetitively to the plasma jet for a sufficient length of time, rotation of the carousel is stopped and the carousel is removed from the reaction chamber. Then each of the carriers is removed from the carousel, rotated 90° so that different wafer edges face down, and then reinserted into the carousel. When this occurs, the relative positions of the slide bars 220 and 264 in grooves 222 and 266 will shift due to gravity and engagement of a different combination of slide bars with each of the abutments 282, with the result that all of the wafer support rods 216, 218, 256 and 258 will assume new positions relative to the wafers. The carousel is then returned to the reaction chamber for further etching as previously described. Subsequently, the carousel is again removed from the reaction chamber, the carriers are rotated 90° in the carriers, and then the carousel and its wafer carriers are returned to the reaction chamber for further etching. This rotation of the carriers also causes all of the wafer support bars to shift their positions. Finally, the carousel is again removed from the reaction chamber, the carriers are again rotated 90°, and reinserted into the openings 232, and the carrier is returned to the reaction chamber for further etching. Again all of the wafer support bars are shifted by the carrier rotation. This four-step etching process assures that edge portions of the wafers that are engaged by the support rods when the carrier is in one orientation will not be blocked off when subsequently the carrier is rotated as described above. This procedure of rotating the carriers overcomes the shadow effect and assures that the edges of the wafers will be etched uniformly.

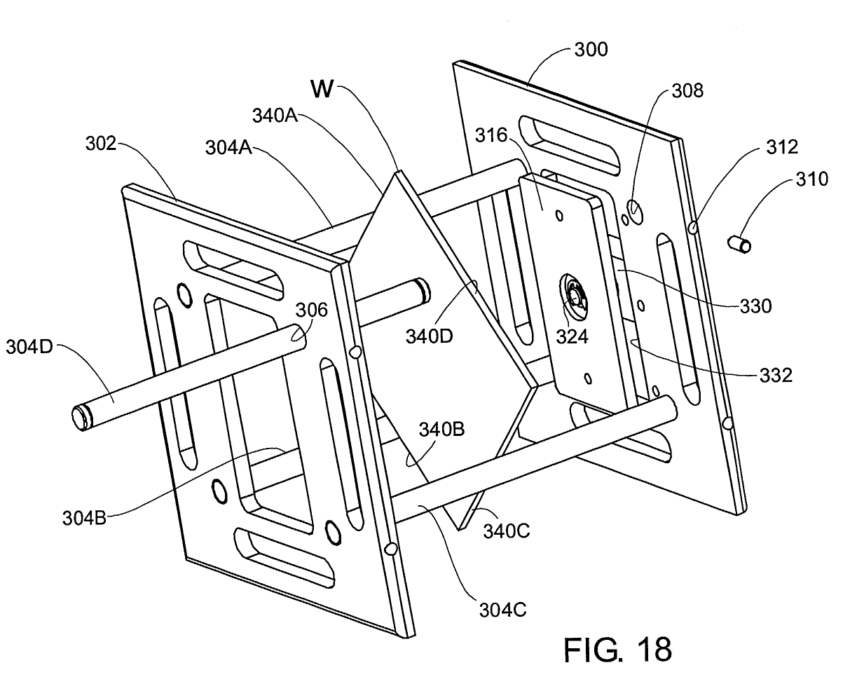

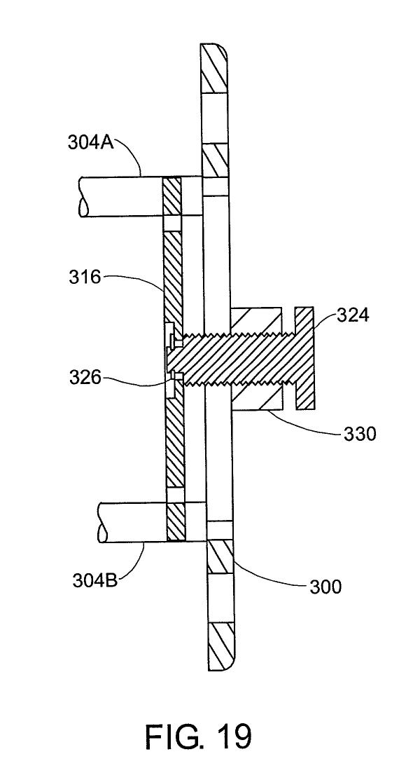

FIGS. 18 and 19 illustrate a third form of carrier provided by the present invention. In this case the carrier comprises a pair of side plates 300 and 302 that are secured together by three parallel standoff or tie rods 304A-C. Rods 304A and 304B are aligned parallel to one side edge of the side plates 300 and 302. The third rod 304C extends parallel to the rods 304A and 304B but is spaced therefrom so that essentially a plane extending through the centers of rods 304A and 304B is at right angles to a plane extending through the centers of rods 304B and 304C. A fourth rod 304D also is provided. However, whereas rods 304A-304C are fixed to side plates 300 and 203, the fourth rod 304D extends slidably through a close-fitting hole 306 in plate 302 and fits into an aligned hole 308 in the other side plate 302. A set screw 310 extends into an intersecting hole 312 in an edge of the plate 302 to hold rod 304D in place. When rod 304D is in place, a plane extending through the centers of rods 304C and 304D is parallel to a plane extending through the centers of rods 304A and 304B. The distance between adjacent rods is the same, so that the four rods form a square.

The carrier of FIGS. 19 and 20 also comprises a rectangular plate 316 that is sized so that it fits within the area defined by the rods 304A-304D. Plate 316 is has a center hole 320 that accommodates the tip of a threaded screw 324. The latter has a peripheral groove to accommodate a snap ring 326 that locks the screw to plate 316, so that the screw can rotate relative to the plate 316 without moving axially. Side plate 300 is provided with a cross-block 330 that extends across a large opening 332 in plate 302 and is secured to the plate by welding or other suitable means. Block 330 has a threaded hole to accommodate the screw 324. Thus, by rotation of screw 324, plate 316 may be advanced toward or away from the plate 302. The purpose of plate 316 is to hold a stack of square wafers, one of which is shown at W, in vertical alignment by urging the stack against side plate 302. Rotation of the screw forces the plate 316 against the adjacent stack of wafers, holding the stack in place. As with the previous embodiments herein described, it is intended that a plurality of square wafers W will be placed in the carrier so that the side edges of the wafers are out of alignment with the sides of end plates 300 and 302 by 900. However, a feature of this carrier design is that the spacing between the rods is such that with the wafer edges 340B and 340C seated on rods 304B and 304C, the latter will engage those wafer edges below their midpoints (as viewed in FIG. 18), and the wafer edges 340A and 340D will be spaced from rods 304A and 304D. Wafers are inserted into the carrier by withdrawing the rod 304D, and placing the wafers in the carrier so that the edges of the wafers rest on rods 304B and 304C. Thereafter, rod 304D is slid back into engagement with slide plate 302, whereby the wafers are confined by rods 304A-304D.

The carrier of FIGS. 18 and 19 offers the advantage of being simple and having the rods 304A-D double as ties rods and wafer supports. Also this form of carrier may be employed with either of the carousels previously described, with the lower edges of the plates 300 and 302 resting on the feet 172 of legs 170 or abutments 282 of legs 280. Because the positions of rods 304-302D are fixed in relation to the side plates, it is necessary to rotate the carriers 90° three times, so that all of the edges are similarly exposed to the plasma jet. Because the rods are spaced so that the wafers touch only the two lowermost rods, e.g., rods 304B and 304C, this form of carrier also compensates for the shadow effect. Although those portions of the edges 340B and 340C engaged with rods 304B and 304C will not be etched like the remainder of those edges, when the carriers are rotated 90° in carousel openings 154, the wafer stacks will shift relative to the fours support rods and different edges of the wafers will be engaged by the support rods. For example, if the carrier in FIG. 18 is rotated clockwise 90° so that support rods 304C and 304D are now on the bottom, the edges 340C and 340D will now be engaged by rods but the point of contact of rod 304C with wafer edges 340C will be different. Accordingly if the carriers are rotated 90° three times so that different pairs of support rods are in the down position, the edges can be etched substantially uniformly.

With all three forms of carriers described above, when a carrier carrying wafers oriented as shown in FIGS. 11 and 18 is rotated through a plasma jet emanating from generator 4 as described above, the two wafer edges on the bottom, e.g., edges 340B and 340C, will undergo etching at a substantially greater rate than the other two edges, e.g., edges 340A and 340D, and the portions of the edges 340B and 340C closest to the plasma generator will exhibit faster etching than those portions which are near the other two higher edges 340A and 340D. Hence, rotation of the wafers is necessary to assure uniform edge etching of stacked wafers. However, because the wafers are etched in stacks, the overall productivity is high and more economical than any other known method of edge etching wafers to eliminate edge defects. Other advantages will be obvious to persons skilled in the art.

The invention is susceptible to changes and modifications. For one thing, the wafers need not be square. Thus, for example, they may be round and arranged in horizontal stacks in the carriers, preferably in carriers of the form shown in FIGS. 3-6. The wafers also may be rectangular, in which case the carriers need to be modified to accommodate the fact that the four sides of the wafers are not of equal length. By way of example, with carriers as shown in FIGS. 3-6, this accommodation can be achieved by varying the length of the arms 48, 50, 86 and 88 and relocating the slots 62, 63, 64, 110, 111, and 112. For another thing, certain of the components of the carousels and carriers may be fixed to one another in ways or by means other than as described and illustrated. Also the number and size of components may be varied. The materials of construction also may be varied provided that they are capable of withstanding the reactive plasma. Still other changes and modifications will be obvious to persons skilled in the art.

What is claimed is:

1. Apparatus for use in edge etching a plurality of flat semiconductor wafers comprising:
a carousel assembly comprising a support plate having a plurality of openings arranged in a circular array, and a support member attached to and projecting from said plate centrally of said openings for attaching said assembly to a carousel drive mechanism; and
a plurality of wafer carriers each mounted in a different one of said openings, each wafer carrier comprising a pair of side plates, and a plurality of mutually spaced wafer support rods extending between said side plates, said wafer support rods being mutually spaced so as to define a space between said side plates to accommodate a plurality of semiconductor wafers having flat opposite side surfaces with said wafers oriented so that said flat opposite surfaces extend parallel to said end plates.

2. Apparatus according to claim 1 wherein said side plates extend perpendicular to said support plate.

3. Apparatus according to claim 1 further including carrier support means depending from said support plate adjacent each of said openings for supporting said carriers in said openings, said carrier support means being engaged with at least one of the side plates of each carrier.

4. Apparatus according to claim 1 wherein said carrier support means comprises first and second members attached to and depending from said support plate adjacent each opening, with each of said first and second members being engaged with one of said side plates.

5. Apparatus according to claim 1 wherein said wafer support rods are disposed in a rectangular arrangement, with two wafer support rods residing in a first plane that extends parallel to said support plate and two wafer support rods residing in a second plane that extends parallel to said support plate.

6. Apparatus according to claim 1 wherein each wafer carrier comprises four parallel wafer support rods disposed in a parallelogram array between said end plates.

7. Apparatus according to claim 1 wherein each of said wafer support rods is movable laterally parallel to the planes of said side plates between first and second limit positions.

8. Apparatus according to claim 1 further including connecting rods affixed to and extending between said side plates.

9. Apparatus according to claim 1 wherein at least one of said wafer support rods is removable.

10. Apparatus according to claim 1 wherein each of said wafer support rods is movable laterally of its longitudinal axis between first and second limit positions.

11. Apparatus according to claim 1 comprising four wafer support rods coupled in pairs, and further including means for shifting said pairs laterally of one another parallel to said end plates.

12. Apparatus according to claim 1 wherein said wafer support rods are coupled to form first and second coupled pairs, and further wherein each of said first and second coupled pairs is pivotable on a pivot axis that is coincident with the longitudinal axis of one of its coupled wafer support rods.

13. Apparatus according to claim 1 wherein said wafer support rods are coupled to form first and second coupled pairs, and further wherein each of said first and second coupled pairs is movable laterally parallel to said end plates between first and second limit positions.

14. Apparatus according to claim 1 wherein said carriers are removable from said openings to permit wafers to be loaded into and unloaded from said carriers.

15. Apparatus according to claim 1 wherein each of said carriers is further characterized in that each of its said end plates comprises first and second parts that abut one another, and further wherein each carrier comprises locking means for releasably locking said first and second parts to one another, said first and second parts of each end plate being separable when said locking means is in its unlocked state to permit wafers to be removed from and supplied to said carrier.

16. A carrier for holding a plurality of semiconductor wafers to be etched, said carrier comprising
a pair of end plates; and
a plurality of mutually spaced rods extending between said end plates, said rods being arranged so that a plurality of flat semiconductor wafers may be positioned between said rods, with said wafers being in face to face engagement with one another and oriented so that their planes extend parallel to said end plates.

17. A carrier according to claim 16 wherein said rods extend parallel to one another in a parallelogram arrangement.

18. A carrier according to claim 16 wherein said rods are arranged to shift laterally.

19. A carrier according to claim 16 wherein said rods are coupled in pairs and said pairs are arranged to shift laterally of one another parallel to said end plates.

20. A carrier according to claim 16 wherein said rods are coupled to form first and second coupled pairs, and further wherein each of said first and second coupled pairs is pivotable on a pivot axis that extends perpendicular to said end plates.

21. A carrier according to claim 16 wherein said rods are movable to permit concealment of different portions of the edges of wafers disposed in said carriers and supported by said rods.

22. A carrier for use in holding a stack of substantially flat and thin crystalline wafers that are to be subjected to etching of their edges, said carrier comprising:
first and second mutually spaced end plates each comprising first and second parts and cooperating means for releasably securing said first and second parts to one another, and
a plurality of elongate means extending between said end plates supporting a stack of crystalline wafers between said end plates with each wafer extending parallel to said end plates.

23. A carrier according to claim 22 further including a plurality of standoff rods attached to and connecting said end plates.

24. A carrier according to claim 22 wherein said first parts of said end plates and certain of said elongate means form a first subassembly and said second parts of said end plates and others of said elongate means form a second subassembly, and further wherein said first and second subassemblies are secured together by said cooperating means.

25. A carrier according to claim 24 wherein said cooperating means comprises grooves in said first parts and rotatable members attached to said second parts and movable into said grooves so as to lock said first and second parts together.

26. A stack of crystalline wafers and a carrier for holding said stack of wafers so that their edges are exposed for contact with an etchant fluid, said carrier comprising:
first and second subassemblies, each subassembly comprising first and second end plates in parallel spaced relation to one another, and first and second parallel wafer support rods extending between and disposed at a right angle to said first and second end plates; and
cooperating means for releasably locking said first and second subassemblies to one another with said wafer support rods of said first subassembly extending parallel to said wafer support rods of said second subassembly.

27. The combination of claim 26 wherein said wafer support rods are movable parallel to said end plates between predetermined first and second wafer supporting positions.

28. The combination of claim 27 wherein said wafer support rods move in an arc when moving between said first and second wafer supporting positions.

29. The combination of claim 27 wherein said wafer support rods move in a straight line when moving between said first and second wafer supporting position.

29. A method of etching the edges of semiconductor wafers of polygonal shape,

30. Method of etching edges of a plurality of planar silicon semiconductor wafers having edge portions that are characterized by micro-cracks, said method comprising placing said wafers into separate carriers with the wafers in each carrier being in face-to-face contact with one another and forming a wafer stack in which their edges are in mutual alignment, providing a carousel having a plurality of like openings disposed in a circular array about the center of said carousel, inserting said carriers in said openings with said coin stacks oriented so that selected edge portions of said wafers face downward, inserting said carousel with said carriers into a reaction chamber containing a plasma generator that generates a vertically-extending plasma jet stream containing halogen ions at substantially atmospheric pressure, suspending said carousel in said chamber over said plasma generator in proximity to said plasma jet stream, and rotating said carousel so that said selected edge portions of the wafers in each stack repetitively move into and out of said plasma with said selected edge portions undergoing incremental etching by contacting said plasma on an intermittent basis.

31. Method according to claim 30 further including the steps of removing said carousel from said reaction chamber, removing said carriers from said openings, rotating said carriers, reinserting said carriers into said openings whereby other selected edge portions of said wafers face downward, returning said carousel to said reaction chamber and re-suspending it above said plasma generator in proximity to said plasma jet stream, and rotating said carousel so that said other selected edge portions of the wafers in each stack repetitively move into and out of said plasma with said other selected edge portions undergoing incremental etching by contacting said plasma on an intermittent basis.
